(19) United States
(12) Patent Application Publication
(10) Pub. No.: US 2008/0081399 A1
(43) Pub. Date: Apr. 3, 2008

(54) Manufacturing Method of Semiconductor Apparatus

(75) Inventors: Yasuhiro Takano, Gunma-ken (JP); Atsushi Mashita, Taipei (TW)

Correspondence Address: SoCAL IP LAW GROUP LLP, 310 N. WESTLAKE BLVD. STE 120, WESTLAKE VILLAGE, CA, 91362, US

(73) Assignees: Sanyo Electric Co., Ltd., Osaka (JP); Sanyo Semiconductor Co., Ltd., Ora-gun (JP)

(21) Appl. No.: 11/863,120

(22) Filed: Sep. 27, 2007

(30) Foreign Application Priority Data
Sep. 29, 2006 (JP) 2006-269131

(51) Int. Cl. H01L 21/00

(52) U.S. Cl. 438/112; 257/E23.01

(57) ABSTRACT

A manufacturing method of a semiconductor apparatus, comprising the steps of: forming a plurality of leads corresponding to a plurality of semiconductor apparatuses on an electrically conductive sheet; disposing a plurality of semiconductor elements in predetermined positions of the electrically conductive sheet; connecting between a bonding pad of a semiconductor element and a lead by a bonding wire, the semiconductor element being included in the plurality of semiconductor elements and the lead being included in the plurality of leads; curving the bonding wire toward an upstream side of a flow path of resin flowing into a metal mold at a time of resin sealing; and resin-sealing the semiconductor element, the lead, and the bonding wire.

### CROSS-REFERENCE TO RELATED APPLICATION

This application claims the benefit of priority to Japanese Patent Application No. 2006-269131, filed Sep. 29, 2006, of which full contents are incorporated herein by reference.

### BACKGROUND OF THE INVENTION

1. Field of the Invention

The present invention relates to a manufacturing method of a semiconductor apparatus.

2. Description of the Related Art

Various trials have been made with respect to miniaturization of semiconductor apparatuses to be mounted in electronic devices such as a cellular phone and a PDA (Personal Digital Assistance). For example, patent reference 1 discloses a technology of restraining a package height of an enclosure package of a junction field effect transistor (J-FET) used for a capacitor microphone, etc., by mounting a semiconductor chip face-down on a lead frame and exposing the back side of an island part of the lead frame to the surface of the package. For example, patent reference 2 discloses reducing a total height of a resin package to 0.33 mm or less in a semiconductor apparatus comprising a semiconductor element mounting region, a plurality of leads disposed so that one end thereof is positioned in the vicinity of the region, a semiconductor chip mounted on the region and electrically connected by way of a bonding wire to at least one of the leads, and the resin package that coats the semiconductor chip and exposes an outer end of the leads to the outside. (See Japanese Patent Application Laid-Open Publication Nos. 2003-218288 and 2005-167004)

In accordance with the demand for the miniaturization/multi-functionalization of the electronic devices in recent years, further miniaturization is now required for semiconductor apparatuses to be installed in such electronic devices as well. For example, the package of the J-FET used for the capacitor microphone is required to have the thickness of 0.30 mm or less and there is in demand the technology of further reducing the thickness of the semiconductor apparatus.

### SUMMARY OF THE INVENTION

A manufacturing method of a semiconductor apparatus according to an aspect of the present invention, comprises the steps of: forming a plurality of leads corresponding to a plurality of semiconductor apparatuses on an electrically conductive sheet; disposing a plurality of semiconductor elements in predetermined positions of the electrically conductive sheet; connecting between a bonding pad of a semiconductor element and a lead by a bonding wire, the semiconductor element being included in the plurality of semiconductor elements and the lead being included in the plurality of leads; curving the bonding wire toward an upstream side of a flow path of resin flowing into a metal mold at a time of resin sealing; and resin-sealing the semiconductor element, the lead, and the bonding wire.

Other features of the present invention will become apparent from descriptions of this specification and of the accompanying drawings.

### BRIEF DESCRIPTION OF THE DRAWINGS

For more thorough understanding of the present invention and advantages thereof, the following description should be read in conjunction with the accompanying drawings, in which:

FIG. 1A is an external perspective view of a semiconductor apparatus 1 according to one embodiment of the present invention;

FIG. 1B is a cross-sectional view of the semiconductor apparatus 1 according to one embodiment of the present invention;

FIG. 1C is a plan view of the semiconductor apparatus 1 according to one embodiment of the present invention;

FIG. 2 is a flow chart of a manufacturing process of the semiconductor apparatus 1 according to one embodiment of the present invention;

FIG. 3A is an explanatory diagram of a back side cutting process of a lead forming process 210 according to one embodiment of the present invention;

FIG. 3B is an explanatory diagram of a back side punching process of the lead forming process 210 to be described as one embodiment of the present invention;

FIG. 3C is an explanatory diagram of a front side punching process of the lead forming process 210 according to one embodiment of the present invention;

FIG. 3D is an explanatory diagram of a disconnecting process of the lead forming process 210 according to one embodiment of the present invention;

FIG. 3E is a diagram of a state of a J-FET 11 after mounted (die-bonded) on a thin-walled part 101a through a die bonding process 211;

FIG. 4 is a plan view of an electrically conductive sheet 20 after the lead forming process 210 according to one embodiment of the present invention;

FIG. 5A is a diagram of a first process of a wire bonding process 212 as according to one embodiment of the present invention;

FIG. 5B is a diagram of a process following the process of FIG. 5A;

FIG. 5C is a diagram of a process following the process of FIG. 5B;

FIG. 5D is a diagram of a process following the process of FIG. 5C;

FIG. 5E is a diagram of a process following the process of FIG. 5D;

FIG. 5F is a diagram of a process following the process of FIG. 5E;

FIG. 5G is a diagram of a process following the process of FIG. 5F;

FIG. 5H is a diagram of a process following the process of FIG. 5G;

FIG. 5I is a diagram of a process following the process of FIG. 5H;

FIG. 5J is a diagram of a process following the process of FIG. 5I;

FIG. 5K is a diagram of a process following the process of FIG. 5J;

FIG. 5L is a diagram of a process following the process of FIG. 5K;

FIG. 5M is a diagram of a process following the process of FIG. 5L;

FIG. 6 is a diagram of a manner of mold resin 13 flowing from a pot 62 into the electrically conductive sheet 20 set to a mold machine according to one embodiment of the present invention;

FIG. 7 is a diagram of a state of bonding wires 12a and 12b according to one embodiment of the present invention; and

FIG. 8 is a diagram of a state of the electrically conductive sheets 20 with one sheet placed over the other after a resin sealing process 213 according to one embodiment of the present invention.

### DETAILED DESCRIPTION OF THE INVENTION

At least the following details will become apparent from descriptions of this specification and of the accompanying drawings.

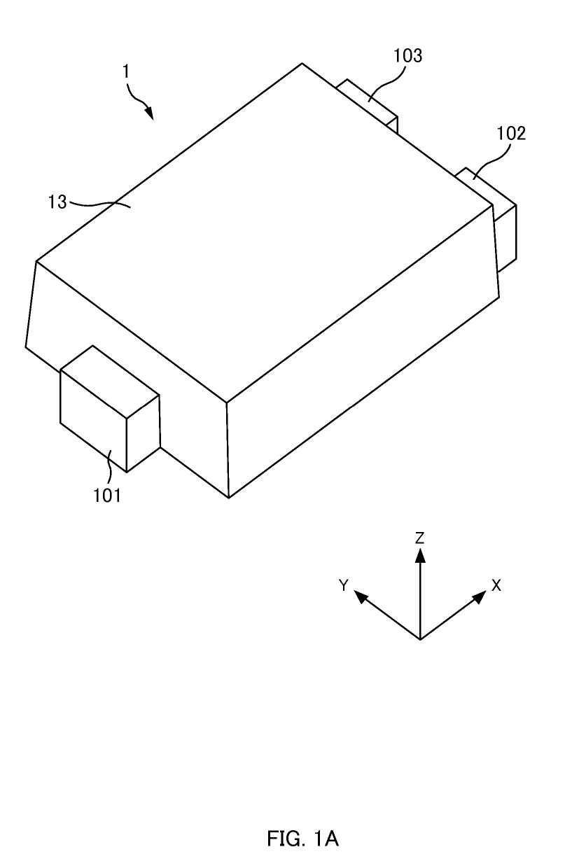

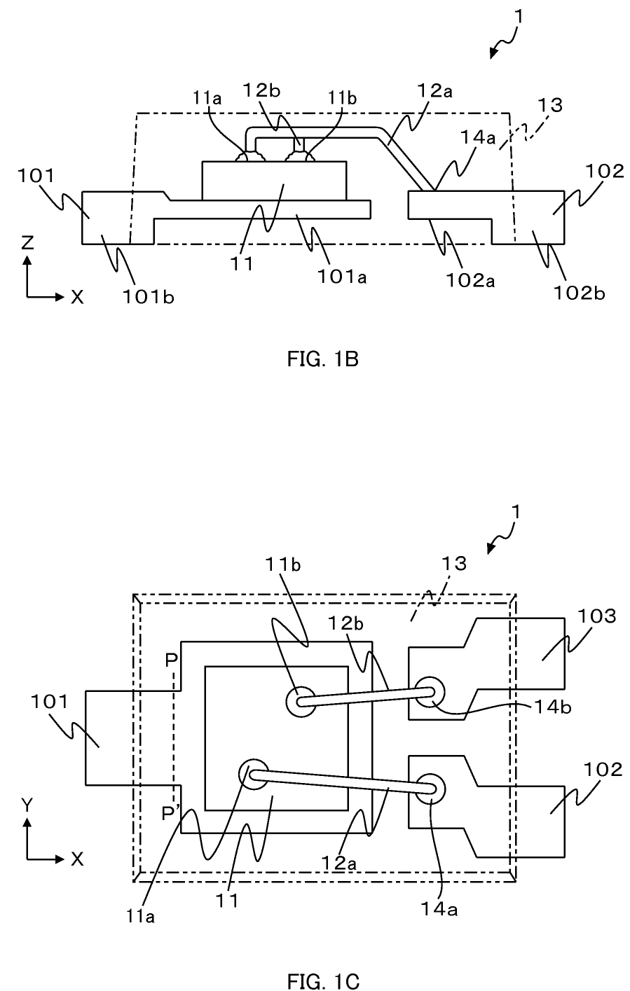

FIG. 1A shows an external perspective view of a semiconductor apparatus 1 that is an electronic device according to one embodiment of the present invention. The semiconductor apparatus 1 according to the present embodiment is of a flat lead package including an element such as a bipolar transistor, a field effect transistor, etc., which are of the three-terminal semiconductor type, the flat lead package being employed for an electret capacitor microphone (C-MIC) to be mounted on a small electronic device such as a cellular phone and a PDA and in this case, is of a rectangular resin package with three exposed leads 101, 102, and 103 corresponding to a drain electrode, a gate electrode, and a source electrode, respectively, of a junction field effect transistor (J-FET). Outer dimensions of the semiconductor apparatus 1 are 1.0 mm in length, 0.6 mm in width, and 0.27 mm in thickness and the semiconductor apparatus 1 has become very thin as compared with a conventional semiconductor apparatus.

FIGS. 1B and 1C show a cross-sectional view and a plan view, respectively, of the semiconductor apparatus 1. As shown in these diagrams, the semiconductor apparatus 1 includes a rectangular parallelepipedic J-FET 11 (semiconductor element) and three leads 101, 102, and 103 connected to three terminals of the J-FET 11.

The J-FET 11 is mounted on the +z-side surface of the lead 101 and the bottom surface (drain electrode) of the J-FET 11 is electrically connected to the lead 101. A bonding pad 11a (source electrode) provided on the +z-side surface of the J-FET 11 and the lead 102 are electrically connected by a bonding wire 12a. A bonding pad 11b (gate electrode) provided on the +z-side surface of the J-FET 11 and the lead 103 are electrically connected by a bonding wire 12b. Whole of the J-FET 11 and the bonding wires 12a and 12b and part of the leads 101, 102, and 103 are resin-sealed by mold resin 13. The leads 101, 102, and 103 are insulated from one another by the intermediate of the mold resin 13.

As shown in FIG. 1B, the lead 101 includes a thin-walled part 101a, which is a part to become primarily an inner lead, and a thick-walled part 101b, which is a part to become primarily an outer lead. The thin-walled part 101a is 40 μm thick and the thick-walled part 101b is 100 μm thick.

The +z-side surface of the thin-walled part 101a is 20 μm concave in the −z direction relative to the +z-side surface of the thick-walled part 101b. That is, protrusion in the +z direction of the J-FET 11 mounted on the lead 101 is reduced by the depth corresponding to this concaved portion, enabling thin configuration of the semiconductor apparatus 1. A bottom surface of the thin-walled part 101a is 50 μm higher than a bottom surface of the thick-walled part 101b and space beneath the bottom surface of the thin-walled part 101a is filled up with the mold resin 13.

On the other hand, the leads 102 and 103 include thin-walled parts 102a and 103a, respectively, which are parts to become primarily inner leads, and thick-walled parts 102b and 103b, respectively, which are parts to become primarily outer leads. Surface heights of the leads 102 and 103 are identical. Bottom surfaces of the thin-walled parts 102a and 103a are 50 μm higher than the bottom surfaces of the thick-walled parts 102b and 103b, respectively, and spaces beneath the bottom surfaces of the thin-walled parts 102a and 103a is filled up with the mold resin 13. Height of the +z-side surface of the lead 101 and heights of the +z-side surfaces of the leads 102 and 103 are identical (of same level).

As described above, the semiconductor apparatus 1 is configured to have the thin-walled part 101a of the lead 101 on which the J-FET is mounted lower than the thick-walled part 101b. As described later, since the bonding wires 12a and 12b are drawn out in substantially horizontal direction from bonding pads 11a and 11b, to be connected to the leads 102 and 103, the protruded portions in the +z direction of the bonding wires 12a and 12b are reduced. That is, these technologies enable realization of the semiconductor apparatus 1 of a thinner type as compared with conventional products.

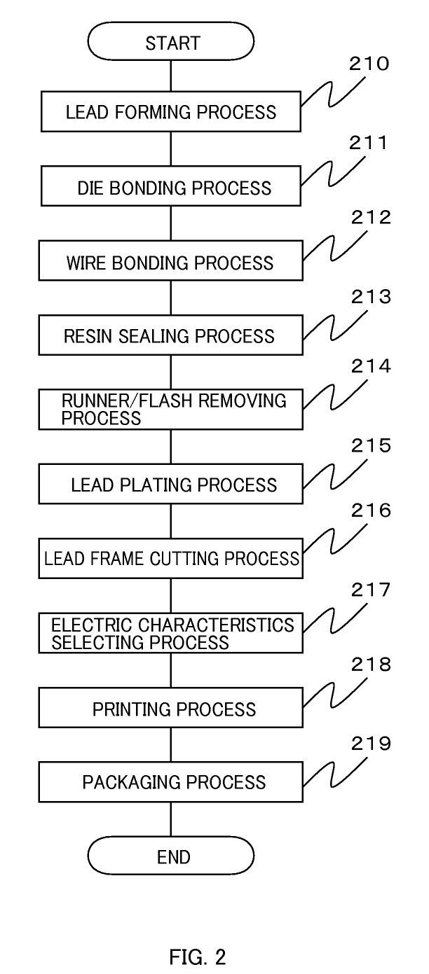

Description will then be made of a manufacturing method of the semiconductor apparatus 1 described above. As shown in FIG. 2, a manufacturing process of the semiconductor apparatus 1 includes a lead forming process 210, a die bonding process 211, a wire bonding process 212, a resin sealing process 213 (molding process), a runner/flash removing process 214, a lead plating process 215, a lead frame cutting process 216, an electric characteristics selecting process 217, a printing process 218, and a packaging process 219. Detailed description will then be made of these processes, in order.

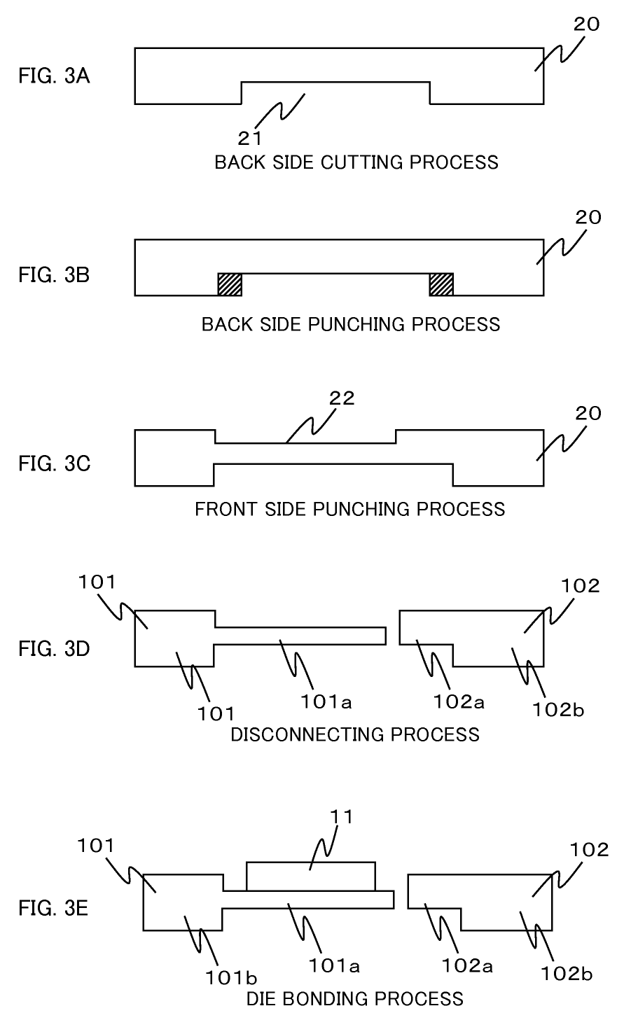

First, in the lead forming process 210, the leads 101, 102, and 103 are formed on a basis of an electrically conductive sheet, which is a plane, substantially rectangular, and 0.1-mm thick sheet including Cu as the main ingredient and including Zn, Sn, and Cr. FIGS. 3A to 3E show details of the lead forming process 210. Here, it is assumed that the electrically conductive sheet 20 includes, for example, Cu, Fe-Ni, Al, etc. as materials.

In the process shown in FIG. 3A, there is formed a rectangular concave portion 21 with a depth of 0.045 mm and a width of 0.6 mm by cutting at a portion corresponding to the thin-walled parts 101a, 102a, and 103a of the leads 101, 102, and 103 from the back side (-z-side) (back side cutting process). In view of accuracy enhancing to be carried out later (FIG. 3B), this cutting is performed so that the dimensions of the external form of the concave part 21 will become slightly smaller than the final dimensions thereof (0.05 mm depth, 0.7 mm width). The concave part 21 may be formed by etching in place of the cutting.

In a following back side punching process shown in FIG. 3B, the accuracy enhancing (0.045 mm→0.05 mm for depth; 0.6 mm→0.7 mm for width) of the external form of the concave part 21 is performed by the punching (crush processing). The accuracy enhancing at this point is required for securing a contact area (implementation region) between the leads 101, 102, and 103 and a wiring board, etc., on which the semiconductor apparatus 1 is implemented. This accuracy enhancing can ensure that the contact area is secured between the leads 101, 102, and 103 and the wiring board, etc., on which the semiconductor apparatus 1 is implemented. By performing the punching (FIG. 3B) after the cutting (FIG. 3A) as described above, the accuracy enhancing of the external form of the concave part 21 can be facilitated.

In a front side punching process shown in FIG. 3C, a flat, rectangular parallelepipedic concave part 22 with a depth of 0.02 mm is formed by punching on the front side (+z-side) of the thin-walled parts 101a, 102a, and 103a. The concave part 22 may be formed by etching in place of the punching.

In a following disconnecting process shown in FIG. 3D, the leads 101, 102, and 103 are formed by blanking processing (disconnection). The leads 101, 102, and 103 are formed by undergoing each of the processes described above.

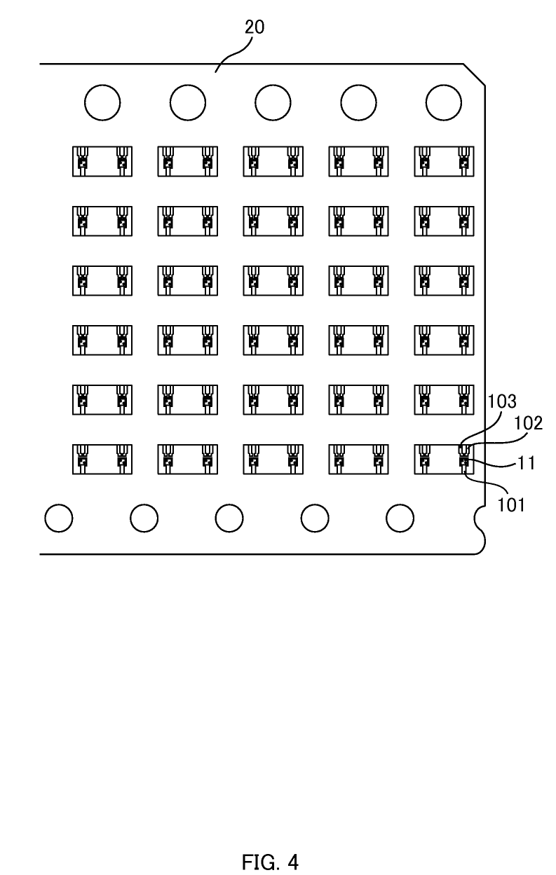

FIG. 4 shows a plan view of the electrically conductive sheet 20 after the lead forming process 210. As shown in FIG. 4, a plurality of leads 101, 102, and 103 are formed on one piece of electrically conductive sheet 20.

To avoid deformation of a product by the punching, it may be so arranged that the leads 101, 102, and 103 of a temporary shape (a shape slightly larger than a final product shape) are blanked in a first part of the back side punching process shown in FIG. 3B.

In the die bonding process 211 in FIG. 2, the J-FET 11 is mounted (die-bonded), by the eutectic method or the resin method, on the surface (+z-side face) of the thin-walled part 101a of each lead 101 formed on the electrically conductive sheet 20. FIG. 3E shows the state after the die bonding process 211 through which the J-FET 11 has been mounted (die-bonded) on the surface of the thin-walled part 101a of the lead 101. In the present embodiments, the mounting of the J-FET 11 is performed by the AuSi eutectic method. To be more specific, first the thin-walled part 101a of the lead 101 is plated with Au (or Ag) at the front-side part thereof to become an island, and then the Au-plated (or Ag-plated) part is mounted with the J-FET 11 and is heated to a high temperature so that the lead 101 is mounted with the J-FET.

The Au (or Ag) plating applied to the part to become the island may be applied before the front side punching process (FIG. 3C) described above. By such a method, the punching changes the crystal structure of the Au (or Ag) plating surface, and thereby the J-FET 11 can be more securely mounted on the lead 101.

In the wire bonding process 212 shown in FIG. 2, the electrically conductive sheet 20 is set to a wire bonding machine and a bonding pad 11a is connected to the lead 102 and a bonding pad 11b is connected to the lead 103 by bonding wires 12a and 12b, respectively.

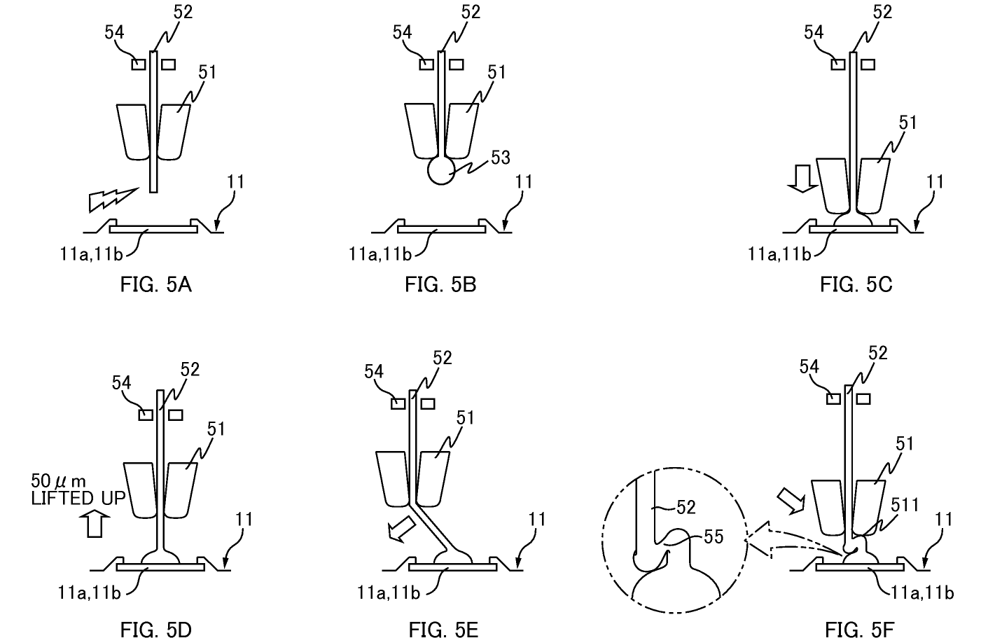

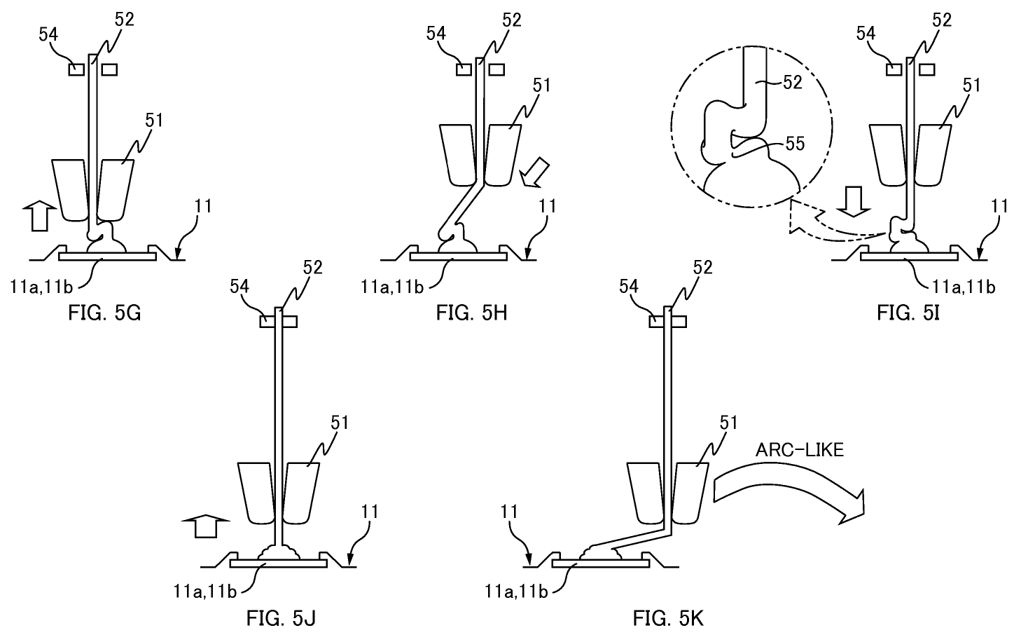

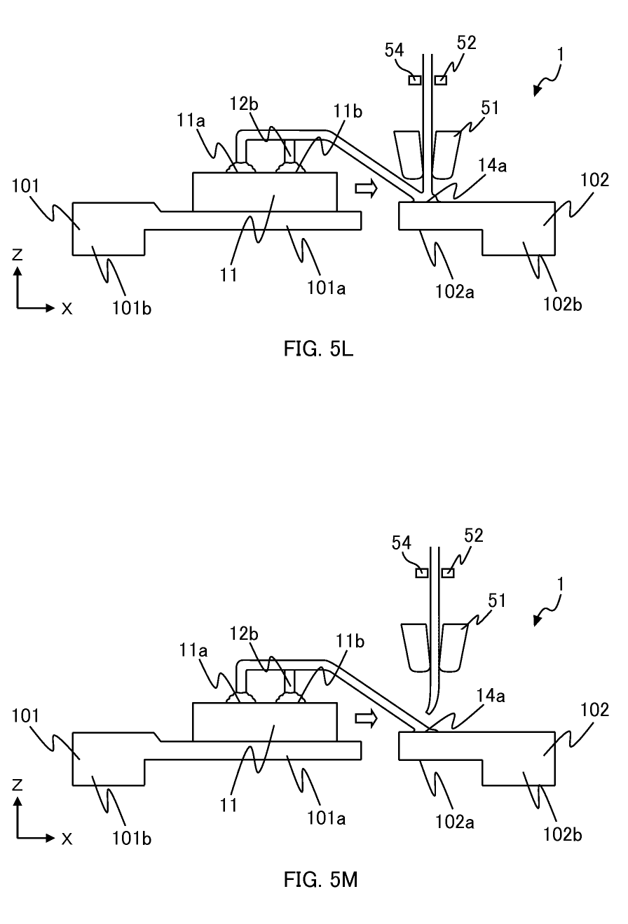

FIGS. 5A to 5M show details of the wire bonding process 212. First, as shown in FIG. 5A, the end (diameter of 20 μm) of a bonding wire 52 inserted into and drawn through a capillary tool 51 is melted by arc discharging, etc., and, as shown in FIG. 5B, to be formed into an Au ball 53 with a diameter of 50 to 80 μm, with the help of the surface tension.

Next, with the capillary tool 51 shifted, the Au ball 53 is pressed against the bonding pad 11a or 11b and, in this state, by giving energy for bonding (supersonic vibration, loading, heating, etc.), the bonding wire 52 is bonded to the bonding pad 11a or 11b (FIGS. 5B and 5C).

Then, after the capillary tool 51 is lifted up (FIG. 5D), the capillary tool 51 is brought down in a slanting direction (direction of about 45° relative to perpendicularity) away from the bonding pad 11a or 11b (FIG. 5E), and is again pressed against the bonding pad 11a or 11b (FIG. 5F). An appearance of and around the bonding pad 11a or 11b at this stage is shown in FIG. 5F. As shown in a magnified view in FIG. 5F, by the above operation of the capillary tool 51, the bonded part is pressed by a head of the capillary tool 51, to form a narrow part 55.

Then, after the capillary tool 51 is again lifted up (FIG. 5G), the capillary tool 51 is brought down in a slanting direction opposite to the slanting direction in FIG. 5E (direction of about 45° relative to perpendicularity) away from the bonding pad 11a or 11b (FIG. 5H), and is again pressed against the bonding pad 11a or 11b. An appearance of and around the bonding pad 11a or 11b at this stage is shown in FIG. 5I. As shown in a magnified view in FIG. 5I, by the above operation of the capillary tool 51, asigmoidally accumulated melted lumps of Au are formed on the bonding pad 11a or 11b in such state that the bonding wire 52 can easily be drawn out in the horizontal direction (the state that the bonding wire 52 is not likely to be disconnected).

Then, with the capillary tool 51 slightly lifted up again (FIG. 5J), by moving the capillary tool 51 in an arc from that position, the bonding wire 52 is drawn out toward the lead 102 or 103 (FIG. 5K). Then, the head of the capillary tool 51 is landed at the bonding position 14a or 14b on the surface of the lead 102 or 103, and the bonding wire 52 is stitch-bonded at this position (FIG. 5L), and is disconnected by closing a wire clamp 54 (FIG. 5M).

The bonding wire is slightly lifted up in FIG. 5J for preventing the bonding wire from getting in contact with the J-FET 11.

By the wire bonding according to the above method, the bonding wire 12a or 12b can be drawn out in substantially a horizontal direction (XY direction) from the bonding pad 11a or 11b without being placed under a high tension or being disconnected. For this reason, bulging in the +z direction of the bonding wire 12a or 12b can be restrained, and accordingly the mold resin 13 can be formed to have a thin wall, thereby the thickness of the product can be restrained.

The occurrence of warpage, deflection, etc. in the lead 101 is restrained in the wire bonding process 212 in spite of the thin-walled part 101a thereof being very thin (40 μm), since the electrically conductive sheet 20 does not include pure copper but includes a high-strength material containing Cu as the main ingredient and containing Zn, Sn, Cr, etc.

In the above, for example, the use of a fine wire (on the order of 20 μm) for the bonding wire 12a or 12b can restrain the load on the lead 101. The use of the fine wire can restrain an occurrence of distortion or stress on a metal surface and can prevent excessive deformation of the bonding wire 12a or 12b.

In the resin sealing process 213 in FIG. 2, the resin sealing is performed by the transfer molding method. In the resin sealing process 213, first, the electrically conductive sheet 20 is set to a metal mold of a mold machine and mold resin 13 is injected under pressure from a pot. At this time, the temperature of the metal mold is set at, for example, around 180° C.

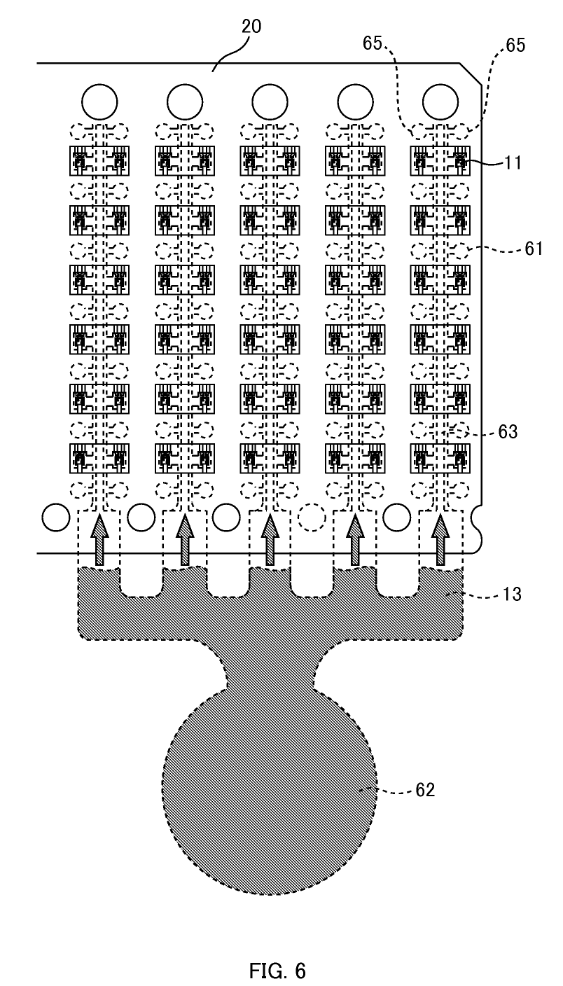

FIG. 6 shows a manner in which the mold resin 13 in melting state flows from the pot 62 into the electrically conductive sheet 20 set to the metal mold 61 of the mold machine. In the same diagram, an “arrow” indicates the inflow direction of the mold resin 13. In the same diagram, a “dashed line” indicates an interior shape of the metal mold 61. As shown in the same diagram, the mold resin 13 flowing from the pot 62 into the metal mold 61 through a runner 63 flows into the inside (cavity) of the metal mold 61 around each of the leads 101, 102, and 103, to fill the space surrounding the leads 101, 102, and 103, the bonding wires 12a and 12b, and the J-FET 11.

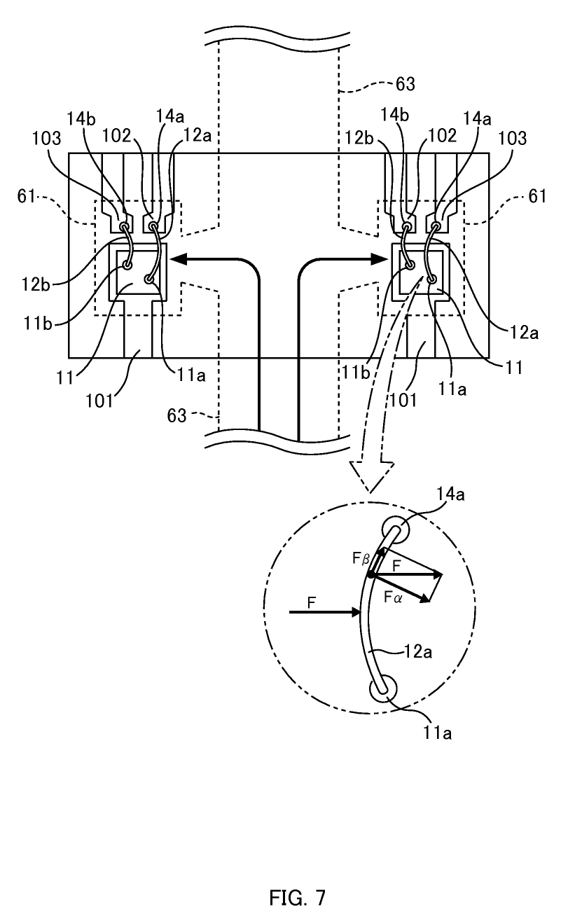

Since the bonding wires 12a and 12b are connected between the J-FET 11 and the lead 102 or 103 in a low position, that is, in a position close to the J-FET 11, as described above, these wires does not have allowance for an external force and it is conceivable that the bonding wires 12a and 12b result in rupture, etc. when being placed under a high tension by the mold resin 13 flowing into the metal mold 61. Therefore, in the present embodiments, the bonding wires 12a and 12b are provided not in a straight line but in a curved state when viewed from the top (see FIG. 7). Also, the curved part of the bonding wires 12a and 12b is curved toward the upstream side of a flow path (flow path indicated by an arrow in FIG. 7) of the mold resin 13 flowing into along the metal mold 61, so that the bonding wires 12a and 12b are not immediately placed under a high tension even if the bonding wires 12a and 12b are pressed by the mold resin 13. To be more specific, as shown in a magnified view of FIG. 7, when a force of magnitude F is applied by the inflow mold resin 13 to a central part of the bonding wire 12a or 12b, the closer the position on which the force F acts is to the bonding pad 11a or 11b or to the bonding position 14a or 14b at which the bonding wire 12a or 12b is bonded to the surface of the lead 102 or 103, the more divided the force F is into: a force F_{β} in a tangential direction of the bonding wire 12a or 12b; and a force F_{α} in a direction perpendicular thereto. For this reason, only the force Fβ, a small force as compared with the force F, is applied to end portions of the bonding wire 12a or 12b, and as a result, the bonding wire 12 can be prevented from rupturing in the proximity of the bonding pad 11a or 11b or the bonding position 14a or 14b.

A plurality of pillar-shaped (cylinder-shaped in the diagram) cavities (hereinafter, referred to as dummy cavities 65) are formed around the leads 101, 102, and 103 in the metal mold 61 set to the mold machine. Therefore, after the molding, a plurality of pillar-shaped resin lumps 14 are formed in uniform thickness and disposed in parallel in the surface of the electrically conductive sheet 20, each resin lump 14 being at region, where the semiconductor apparatus 1 is not made up, on the front side and the back side of the electrically conductive sheet 20 (at the position corresponding to that of the dummy cavity).

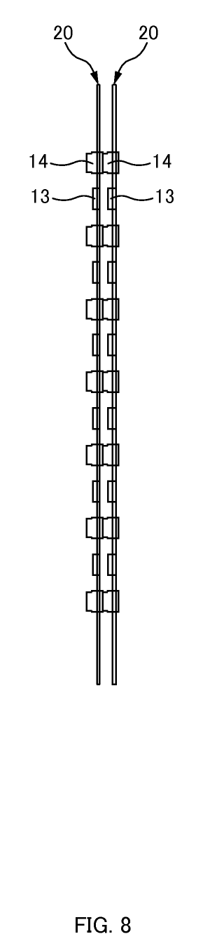

When the electrically conductive sheets 20 are stored in superposed relation, for example, as shown in FIG. 8, the resin lumps 14 serve to prevent products formed on the upper and lower electrically conductive sheets 20 from interfering with one another. That is, the resin lumps 14 formed on one electrically conductive sheet 20 contact with the resin lumps 14 of other electrically conductive sheets 20 above and below the one electrically conductive sheet 20, thereby supporting the electrically conductive sheet 20 and such parts of the product as the leads 101, 102, and 103 and the J-FET 11 do not directly come into contact with members provided on the electrically conductive sheets 20 above and below the one electrically conductive sheet 20 and, as a result, the product can be prevented from being damaged and the electrically conductive sheet 20 can be stored efficiently and safely.

By arranging the position of the resin lump 14 so that an eject pin of the mold machine used for removing the electrically conductive sheet 20 from the mold machine contacts with a part of the resin lump 14, such parts of the product as the leads 101, 102, and 103 and the J-FET 11 can be prevented more securely from damage caused by the contact of the eject pin. By arranging the position of the resin lumps 14 so that the resin lumps 14 are distributed all over the entire electrically conductive sheet 20, it can be ensured that a force in a bending direction is not applied to the electrically conductive sheet 20 in such cases as storing the electrically conductive sheets 20 in superposed relation, thereby deformation and damage thereof can be prevented.

By setting the diameter of the top surface of the resin lump 14 larger than that of the eject pin, it can be ensured that the eject pin contacts with the resin lump and the product can be prevented from being damaged due to the contact of the eject pin with a part of the product. By securing sufficient diameter of the top surface of the resin lump 14 to allow the use of the eject pin with a greater diameter, durability of the eject pin can be enhanced.

While the resin lump 14 is pillar-shaped in the present embodiments, the shape of the resin lump 14 is not to be limited to this, but can take various shapes other than this, such as a square pillar shape, according to the function and usage required of the resin lump 14.

In the runner/flash removing process 214 in FIG. 2, runner parts and flashes are removed by a high-pressure water method, a liquid honing method, etc. In the lead plating process 215 in FIG. 2, the plating processing is applied to the leads 101, 102, and 103 for armoring. In the lead frame cutting process 216 in FIG. 2, the leads 101, 102, and 103 formed on the electrically conductive sheet 20 are separated, by cutting, from a frame part (lead frame), to form a unit product.

In the electric characteristics selecting process 217 in FIG. 2, electric characteristics of the unit product are measured. In the printing process 218 in FIG. 2, a product name, a company name, a manufacturing history symbol, etc., are printed by a laser, etc., on the semiconductor apparatus 1 judged as conforming product according to the measured electrical characteristics. In the packaging process 219 in FIG. 2, single-unit semiconductor apparatus 1 is nested into an embossed tape and is covered by a cover tape with thermocompression bonding. Thereafter, the semiconductor apparatus 1 on the tape is wound up on a reel and becomes a finished product.

As described above, at the time of the resin sealing, by curving the bonding wire toward the upstream side of the flow path of the resin flowing into the metal mold, the bonding wire can have an allowance, and is not immediately placed under the high tension even if the bonding wire is pressed by the mold resin in the inflow thereof, and thereby the bonding wire can be prevented from rupturing.

The bonding wire can be drawn out in a horizontal direction from the bonding pad, thereby enabling realization of a thinner type semiconductor apparatus. When the bonding wire is drawn out in a horizontal direction as described above, the bonding wire is likely to rupture at the time of resin sealing, but as described above, by curving the bonding wire toward the upstream side of the flow path of the resin flowing into the metal mold, the bonding wire can have an allowance, thereby the bonding wire can be prevented from rupturing. That is, the present invention enables enhancement of product yield while realizing a thinner type semiconductor apparatus.

According to the above process, since the semiconductor element is mounted on the concave part 22, the protrusion of the semiconductor element can be reduced by the depth corresponding to the concaved portion of the concave part 22. Therefore, further thinner type semiconductor apparatus can be realized.

The above embodiments of the present invention are simply for facilitating the understanding of the present invention and are not in any way to be construed as limiting the present invention. The present invention may variously be changed or altered without departing from its spirit and encompass equivalents thereof.

For example, dimensions of various kinds of members shown in the above description are only one example, and the scope of the present invention is not necessarily to be limited to the dimensions shown in the present embodiments. While the semiconductor element is the J-FET in the above embodiments, the present invention can be applied to cases in which the semiconductor element is semiconductor apparatus other than the J-FET and eventually can be widely applied to electronic devices in general.

It is claimed:

1. A manufacturing method of a semiconductor apparatus, comprising the steps of:
forming a plurality of leads corresponding to a plurality of semiconductor apparatuses on an electrically conductive sheet;
disposing a plurality of semiconductor elements in predetermined positions of the electrically conductive sheet;
connecting between a bonding pad of a semiconductor element and a lead by a bonding wire, the semiconductor element being included in the plurality of semiconductor elements and the lead being included in the plurality of leads;
curving the bonding wire toward an upstream side of a flow path of resin flowing into a metal mold at a time of resin sealing; and
resin-sealing the semiconductor element, the lead, and the bonding wire.

2. The manufacturing method of the semiconductor apparatus of claim 1, wherein
connecting between the bonding pad of the semiconductor element and the lead by the bonding wire further comprises the steps of:
forming a ball at an end of the bonding wire;
pressing the ball against the bonding pad;
lifting up the bonding wire, thereafter bringing down the bonding wire in one slanting direction away from the bonding pad, and again pressing the bonding wire against the bonding pad;
lifting up the bonding wire, thereafter bringing down the bonding wire in the other slanting direction, opposite to the one slanting direction, away from the bonding pad, and again pressing the bonding wire against the bonding pad; and
drawing out the bonding wire in an arc and landing the bonding wire on a lead other than the lead.

3. The manufacturing method of the semiconductor apparatus of claim 1, further comprising the steps of:
forming the lead, by forming a first concave part in a first region on a back side of the electrically conductive sheet, and by forming a second concave part in a second region on a front side of the electrically conductive sheet, the second region corresponding to a region in which the first concave part is formed; and
mounting the semiconductor element on the second concave part, when disposing the plurality of semiconductor elements in the predetermined positions of the electrically conductive sheet.

4. The manufacturing method of the semiconductor apparatus of claim 2, further comprising the steps of:
forming the lead, by forming a first concave part in a first region on a back side of the electrically conductive sheet, and by forming a second concave part in a second region on a front side of the electrically conductive sheet, the second region corresponding to a region in which the first concave part is formed; and
mounting the semiconductor element on the second concave part, when disposing the plurality of semiconductor elements in the predetermined positions of the electrically conductive sheet.
